(19) United States
(12) Patent Application Publication
(10) Pub. No.: US 2025/0267833 A1
(43) Pub. Date: Aug. 21, 2025

(54) SEMICONDUCTOR DEVICE AND METHOD FOR MANUFACTURING THE SAME

(71) Applicant: TAIWAN SEMICONDUCTOR MANUFACTURING COMPANY LTD., HSINCHU (TW)

(72) Inventors: TOYOYUKI HAGIWARA, HSINCHU (TW); HUI WEN LIU, HSINCHU COUNTY (TW); CHIEN-YING CHEN, CHIAYI COUNTY (TW); KU-FENG LIN, NEW TAIPEI CITY (TW); YI-TZU CHEN, HSINCHU CITY (TW)

(21) Appl. No.: 18/444,797

(22) Filed: Feb. 19, 2024

(51) Int. Cl. H10B 10/00

(52) U.S. Cl. CPC H10B 10/12

(57) ABSTRACT

A semiconductor device and a method for manufacturing the semiconductor device are provided. The semiconductor device includes a first back metal structure, a second back metal structure and a first front metal structure. The first back metal structure is formed on the back side of the wafer and extending along a first direction. The second back metal structure is formed on the back side of the wafer and extending along the first direction, wherein the second back metal structure is spaced apart from the first back metal structure along a second direction perpendicular to the first direction. The first front metal structure is formed on the front side of the wafer and extending along the first direction. The width of the first back metal structure along the second direction is greater than a width of the first front metal structure along the second direction.

### BACKGROUND

The present disclosure relates, in general, to semiconductor devices and methods for manufacturing the same. Specifically, the present disclosure relates to semiconductor devices and methods for manufacturing semiconductor devices with super power rails for power delivery.

Integrated circuits that involve semiconductor devices are essential for many modern applications. Technological advances in materials and design have produced semiconductor devices composed of smaller and more complex elements each generation. Although power consumption per element is reduced by miniaturization and reductions in voltage of elements, power consumption of the entire integrated circuit is rising due to increase in the number of elements. Therefore, a novel design with super power rails is needed to control power delivery and improve computing performance.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1 is a schematic view of a semiconductor device on a wafer with multiple power rails, in accordance with some embodiments of the present disclosure.

FIG. 2A is a circuit diagram of a semiconductor device, in accordance with some embodiments of the present disclosure.

FIG. 2B is a design layout of another semiconductor device, in accordance with some embodiments of the present disclosure.

FIG. 2C includes a schematic view and a cross-section of a semiconductor device along lines S1 and S2 in FIG. 2B, in accordance with some embodiments of the present disclosure.

FIG. 2D is a design layout of another semiconductor device, in accordance with some embodiments of the present disclosure.

FIG. 3A is a schematic diagram of a semiconductor device, in accordance with some embodiments of the present disclosure.

FIG. 3B is a schematic diagram of another semiconductor device, in accordance with some embodiments of the present disclosure.

FIG. 3C is a design layout of a semiconductor device, in accordance with some embodiments of the present disclosure.

FIG. 3D is a cross-section of a semiconductor device along line S3 in FIG. 3C, in accordance with some embodiments of the present disclosure.

FIG. 4A is a schematic view of a semiconductor device, in accordance with some embodiments of the present disclosure.

FIG. 4B is a cross-section of a semiconductor device along line S4 in FIG. 4A, in accordance with some embodiments of the present disclosure.

FIG. 4C is a schematic view of another semiconductor device, in accordance with some embodiments of the present disclosure.

FIG. 5 is a flowchart of manufacturing a semiconductor device on a wafer with super power rails, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

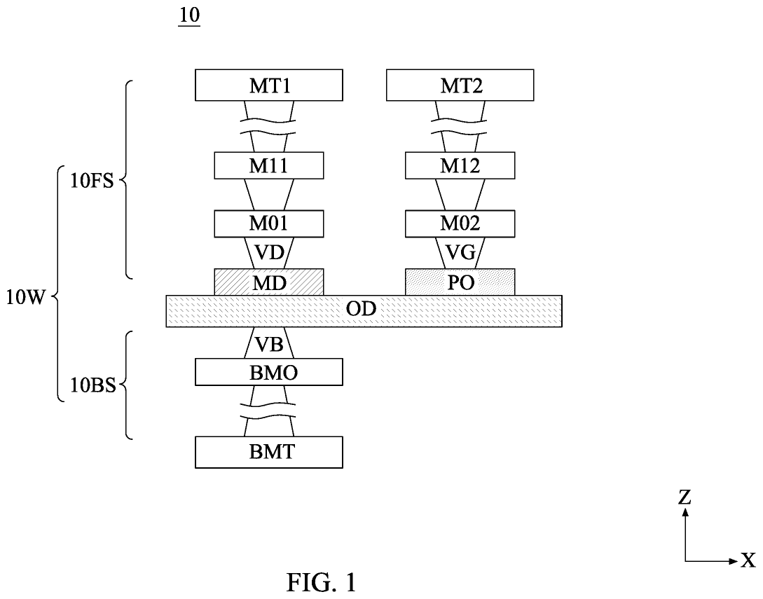

FIG. 1 is a schematic view of a semiconductor device 10 on a wafer 10W with multiple power rails, in accordance with some embodiments of the present disclosure. The semiconductor device 10 can include, for example, an N-type metal-oxide-semiconductor (NMOS) device, a P-type metal-oxide-semiconductor (PMOS) device, a complementary metal-oxide-semiconductor (CMOS) device, and can be implemented using a planar field-effect transistor (FET) device, a fin-type FET (FinFET) device, a gate-all-around (GAA) device, a nanowire device, a fully-depleted silicon-on-isolator (FDSOI) device, or the like. The wafer 10W includes a semiconductor substrate and optionally various layers formed thereon. The wafer 10W includes a front side 10FS and a back side 10BS. The front side 10FS is opposite the back side 10BS. The semiconductor device 10 can belong to a super power rail (SPR) chip design which includes or provides a power delivery network through the front side 10FS and the back side 10BS of the wafer 10W.

Referring to FIG. 1A, the semiconductor device 10 spans the front side 10FS and the back side 10BS. The semiconductor device 10 includes an active region OD, a metal layer structure MD, a gate structure PO, several via structures VD, VG, VB, and multiple metal structures MT1 to BMT. The metal structures MT1 to BMT, the metal layer structure MD, and the via structures VB to VG can be made of metal, such as copper, aluminum, tungsten, titanium, tantalum, an alloy thereof or the like, and are electrically insulated by dielectric materials (not separately shown) such as oxide, nitride, oxynitride and the like.

The active region OD extends along an X direction. The active region OD can be referred to herein as oxide-diffusion (“OD”) regions. The active region OD can be an N-type active region. The active region OD can be a P-type active region. The active region may be used to form source/drain regions and a channel region between the source/drain regions of a transistor device.

In some embodiments, the metal layer structure MD and the gate structure PO are disposed in the front side 10FS and formed above the active region OD along the Z direction, which is perpendicular to the X direction. The metal structures M01, M02, M11, M12, MT1, and MT2 are disposed in the front side 10FS, and formed above the metal layer structure MD or the gate structure PO along the Z direction. The metal structures M01, M02, M11, M12, MT1, and MT2 can be provided in different layers stacking along the Z direction. The metal structures BM0 and BMT are disposed in the back side 10BS, and they are provided below the active region OD along the Z direction.

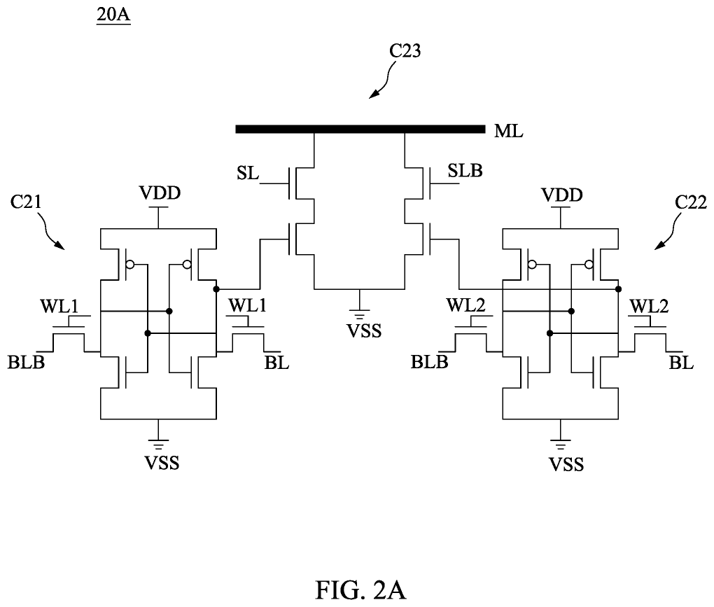

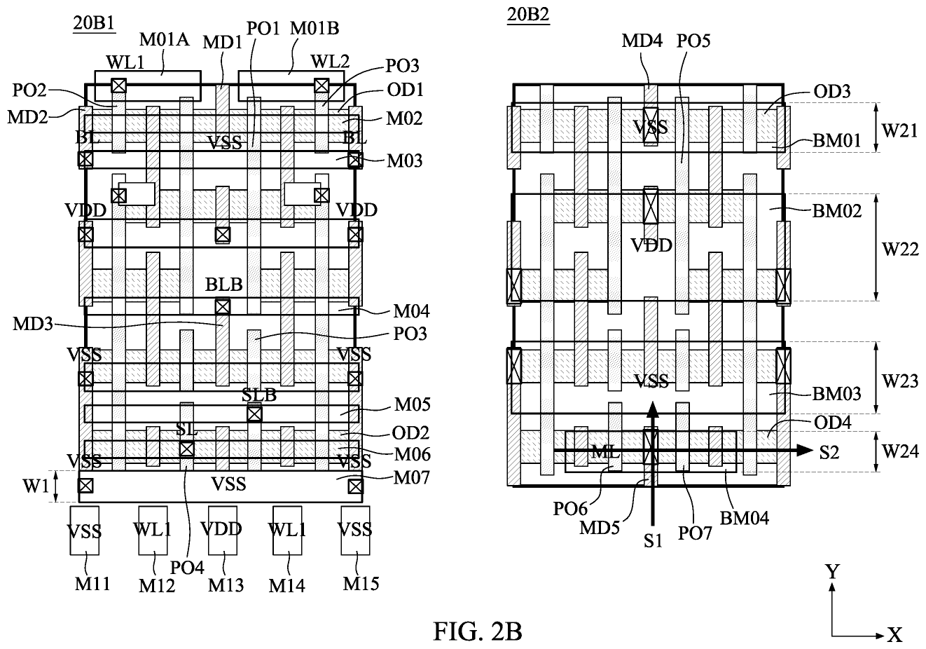

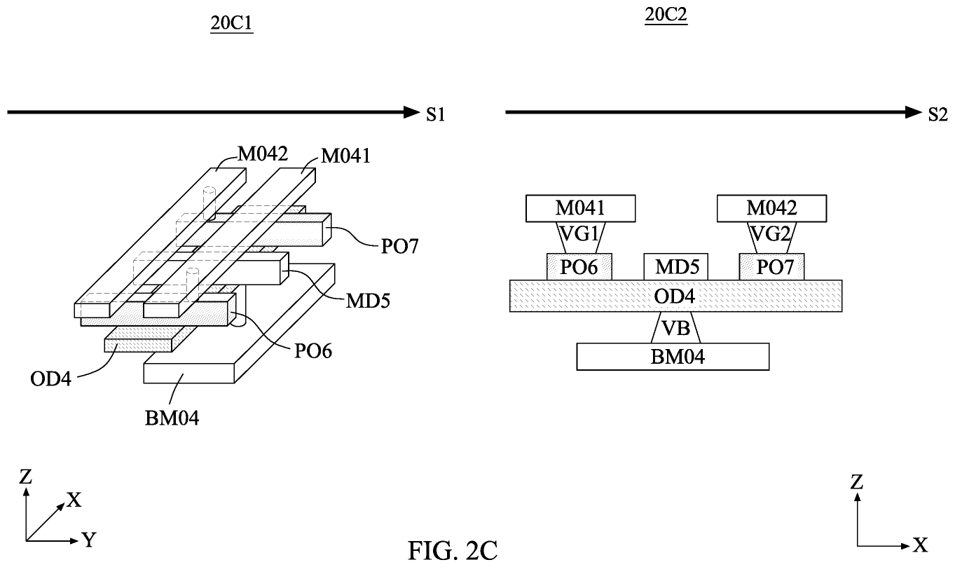

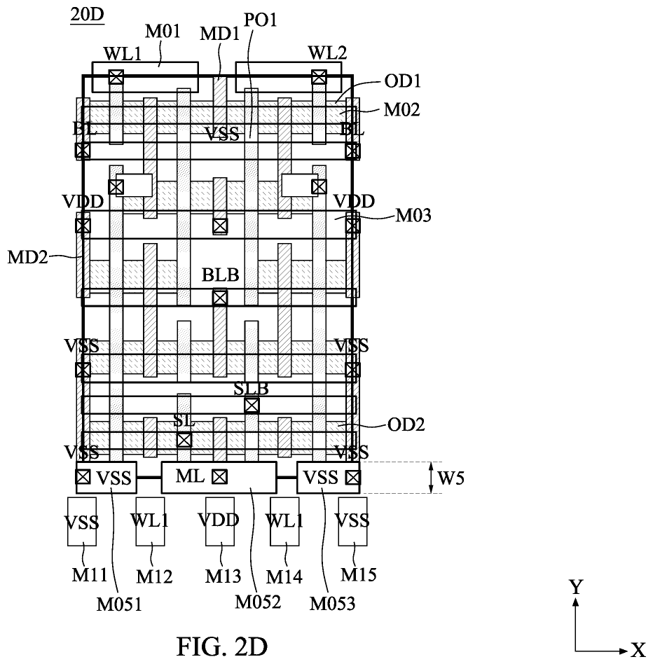

FIG. 2A is a circuit diagram of a semiconductor device 20A, in accordance with some embodiments of the present disclosure. The semiconductor device 20A of FIG. 2A can correspond to the semiconductor device 10 of FIG. 1.

As shown in FIG. 2A, the semiconductor device 20A includes three circuits C21, C22 and C23. The circuits C21 and C22 can correspond to or function as static random-access memory (SRAM) devices. The circuits C21 and C22 are powered by multiple power lines, such as the voltage sources VDD and VSS. The circuit C21 can be operated in response to various signal lines, including the bit line BL, the bit line bar BLB and the word line WL1. The circuit C22 can be operated in response to various signal lines, including the bit line BL, the bit line bar BLB (which is reverse to the bit line BL) and the word line WL2. The circuit C23 electrically connects the circuits C21 and C22. The circuit C23 can be powered by the voltage source VSS and operated in response to various signal lines, including the match line ML, the search line SL and the search line bar SLB (which is reverse to the search line SL). The circuit C23 can operate as a comparator to determine whether the input data matches the stored data.

FIG. 2B is a design layout of the semiconductor devices 20B1 and 20B2, in accordance with some embodiments of the present disclosure. The semiconductor devices 20B1 and 20B2 can correspond to the semiconductor device 20A of FIG. 2A and the semiconductor device 10 of FIG. 1. In particular, the semiconductor device 20B1 can be formed on or correspond to the front side 10FS in FIG. 1, and the semiconductor device 20B2 can be formed on or correspond to the back side 10BS in FIG. 1.

Regarding the semiconductor device 20B1, the metal structures M01A, M01B, M02, M03, M04, M05, M06 and M07 extend along the X direction. The metal structures M11, M12, M13, M14 and M15 extend along the Y direction. The metal structures M11 to M15 can be formed above the metal structures M01A, M01B, M02, M03, M04, M05, M06 and M07 from a top-view perspective of the design layout. The active regions OD1 and OD2 extend along an X direction. The metal layer structures MD1, MD2 and MD3 extend along a Y direction. The gate structures PO1, PO2, PO3 and PO4 extend along a Y direction. The metal structure M07 has a width W1 along the Y direction.

As shown in FIG. 2B, the word line WL1 intersects with the metal structure M01A and the gate structure P02. The word line WL2 intersects with the metal structure M01B and the gate structure P03. The two bit lines BL intersect with the two ends of the metal structure M03. The bit line bar BLB intersects with the metal structure M04 and the metal layer structure MD3. The search line SL intersects with the metal structure M06 and the gate structure PO4. The search line bar SLB intersects with the metal structure M05 and the gate structure PO3. The metal structure M07 is electrically connected the voltage source VSS. The metal structures M11 and M15 are electrically connected the voltage source VSS. The metal structures M12 and M14 are electrically connected to the word line WL1. The metal structure M13 is electrically connected to the voltage source VDD.

In some embodiments, the metal structure M02 overlaps with the active region OD1 from a top-view perspective of the design layout. The width of the metal structure M02 is shorter than the width of the active region OD1 along a Y direction. The two metal structures M01A and M01B are spaced apart by the metal layer structure MD1. The active region OD2 is void of overlapping with all of the metal structures M01 to M07 from a top-view perspective of the design layout. The width W1 of the metal structure M07 can exceed those of the metal structures M01 to M06.

Regarding the semiconductor device 20B2, the metal structures BM01, BM02, BM03 and BM04 extend along an X direction. The active regions OD3 and OD4 extend along an X direction. The metal layer structures MD4 and MD5 extend along a Y direction. The gate structures PO5, PO6 and PO7 extend along a Y direction. The metal structure BM01 overlaps with the active region OD3 from a top-view perspective of the design layout. The active region OD3 can be within the metal structure BM01 from a top-view perspective of the design layout.

The metal structure BM04 overlaps with the active region OD4 from a top-view perspective of the design layout. The width of the metal structure BM04 is greater than the width of the active region OD4 along a Y direction. The metal structure BM04 is shorter than the active region OD4 along an X direction.

The metal structure BM01 can be electrically connected to the voltage source VSS. The metal structure BM02 can be electrically connected to the voltage source VDD. The metal structure BM03 can be electrically connected to the voltage source VSS. The metal structure BM04 can be electrically connected to the match line ML. In some embodiments, one of the metal structure BM01 to BM04 can be used to electrically connect the read bit line RBL. One of the metal structures BM01 to BM04 can be used to electrically connect the read bit line bar RBLB. The semiconductor device 20B2 is not electrically connected to the word line WL and the bit line BL. The word line WL and the bit line BL are electrically connected to the semiconductor device 20B1 on the front side. Both of the semiconductor device 20B1 on the front side and the semiconductor device 20B2 on the back side can be electrically connected to the voltage source VDD or VSS.

The metal structure BM01 has a width W21 along a Y direction. The metal structure BM02 has a width W22 along a Y direction. The metal structure BM03 has a width W23 along a Y direction. The metal structure BM04 has a width W24 along a Y direction. The widths W21 to W24 can be different from each other. The width W22 is greater than the widths W21, W23 and W24. Each of the widths W21 to W24 is greater than the width WI of the semiconductor device 20B1. Each of the widths W21 to W24 can be three to four times of the width W1 of the semiconductor device 20B1. Therefore, the resistance and the metal capacitance of the metal structures BM01 to BM04 can be decreased, and the electronic migration and the IR drop which is proportional to resistance can be improved.

As shown in FIG. 2B, some of the signal lines, such as the match line ML, can be moved from the front side of the wafer to the back side of the wafer. Since the back side can have more routing space than the front side, the width W24 of the metal structure BM04 of the semiconductor device 20B2 can exceed width W1 of the metal structure M04 of the semiconductor device 20B1. The resistance and the metal capacitance of the metal structure BM04 is lower than those of the metal structure M04. Therefore, the computing speed and the power consumption can be improved accordingly.

FIG. 2C shows a schematic view and a cross-section of the semiconductor devices 20C1 and 20C2 along lines S1 and S2 in FIG. 2B, in accordance with some embodiments of the present disclosure. The semiconductor devices 20C1 and 20C2 can correspond to the semiconductor device 20B2 of FIG. 2B. The section lines S1 and S2 are parallel to the Y direction and the X direction respectively.

Regarding the semiconductor devices 20C1, the active region OD4 is disposed above the metal structure BM04 along a Z direction. The gate structures PO6 and PO7 and the metal layer structure MD5 are disposed above the active region OD4 along a Z direction. The metal structures M041 and M042 are disposed above the gate structures PO6 and PO7 and the metal layer structure MD5 along a Z direction. The metal structures M041 and M042 can extend along an X direction. The metal structure M041 can be electrically connected to the search line SL. The metal structure M042 can be electrically connected to the search line bar SLB. The metal structure M041 can partially overlap with one side of the metal structure BM04 from a top-view perspective. The metal structure M042 can partially overlap with another side of the metal structure BM04 from a top-view perspective. The metal structures M041 and M042 can be formed on the front side of the wafer. The metal structures M041 and M042 can be formed on the back side of the wafer.

Regarding the semiconductor devices 20C2, the active region OD4 is disposed above the metal structure BM04 along the Z direction through the via structure VB. The metal structure M041 is disposed above the gate structure PO6 along the Z direction through the via structure VG1. The metal structure M042 is disposed above the gate structure PO7 along the Z direction through the via structure VG2.

FIG. 2D is a design layout of the semiconductor device 20D, in accordance with some embodiments of the present disclosure. The semiconductor device 20D is formed on the front side of the wafer. The semiconductor device 20D of FIG. 2D can be similar to the semiconductor device 20B1 of FIG. 2B, differing therefrom only as follows.

Three metal structures M051, M052 and M053 are arranged in a row along an X direction. The metal structures M051, M052 and M053 have a width W5 along a Y direction. The metal structures M051, M052 and M053 are spaced apart from each other. The metal structures M051, M052 and M053 are provided between the active region OD2 and the metal structures M11 to M15. The metal structure M051 can be electrically connected to the voltage source VSS. The metal structure M052 can be electrically connected to the match line ML. The metal structure M053 can be electrically connected to the voltage source VSS.

Please refer to FIG. 2D. Due to the intense routing of the metal structures and active regions extending along an X direction, the space is limited and the width W5 is minimal. In some embodiments, the width W5 in FIG. 2D is less than the widths W21, W22, W23 and W24 of FIG. 2B. As a result, the resistance will be increased accordingly, which might deteriorate the computing speed and the power consumption of the semiconductor device 20D.

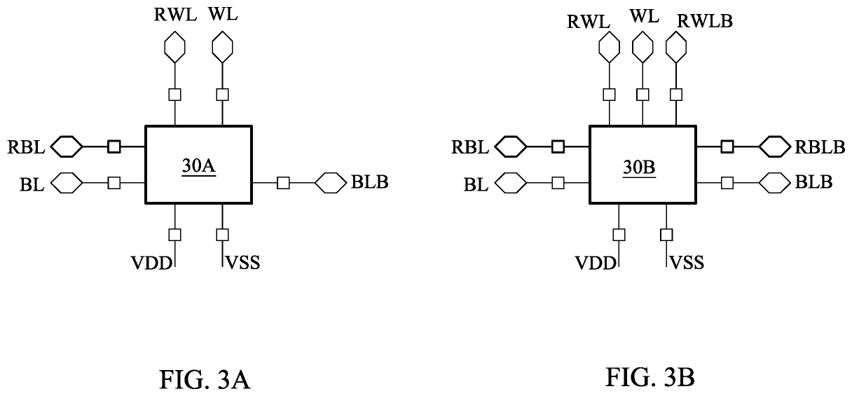

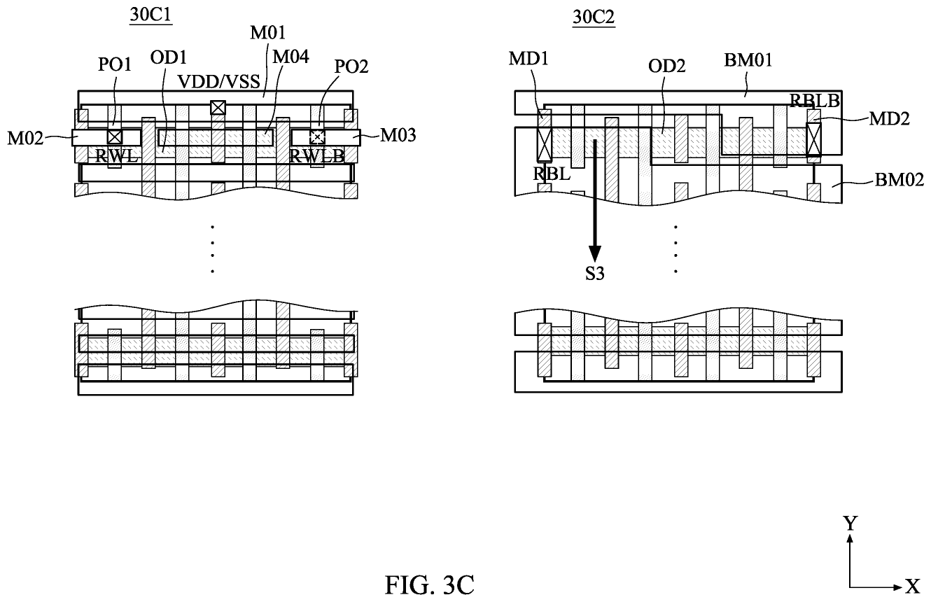

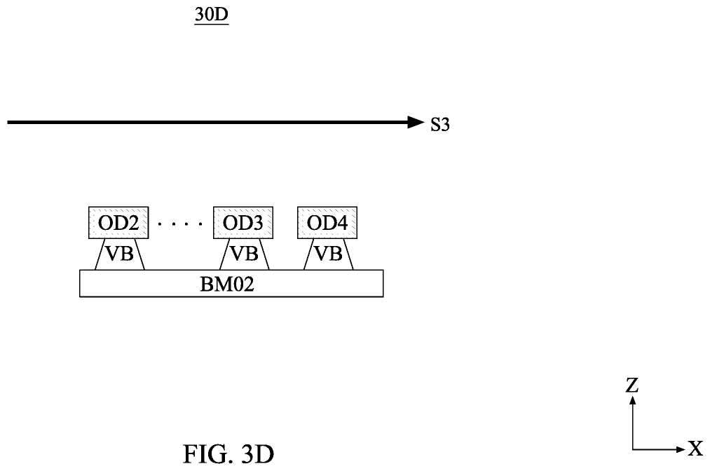

FIG. 3A is a schematic diagram of the semiconductor device 30A, in accordance with some embodiments of the present disclosure. The semiconductor device 30A of FIG. 3A can correspond to or be similar to the semiconductor devices 20B1 and 20B2 of FIG. 2B. In some embodiments, the semiconductor device 30A can be a multi-port memory device, such as multi-port SRAM device, which includes 7 transistors for each bit cell. The semiconductor device 30A can include 5 ports. As shown in FIG. 3A, the 5 ports can be electrically connected to the read word line RWL, the word line WL, the bit lint bar BLB, the bit line BL and the read bit line RBL for operating the semiconductor device 30A.

FIG. 3B is a schematic diagram of the semiconductor device 30B, in accordance with some embodiments of the present disclosure. The semiconductor device 30B of FIG. 3B can correspond to or be similar to the semiconductor devices 20B1 and 20B2 of FIG. 2B. In some embodiments, the semiconductor device 30B can be a multi-port memory device, such as multi-port SRAM device, which includes 8 transistors for each bit cell. The semiconductor device 30B can include 7 ports. As shown in FIG. 3B, the 7 ports can be electrically connected to the read word line RWL, the word line WL, the read word line bar RWLB, the read bit lint bar RBLB, the bit lint bar BLB, the bit line BL and the read bit line RBL for operating the semiconductor device 30B.

FIG. 3C is a schematic diagram of a design layout of the semiconductor devices 30C1 and 30C2, in accordance with some embodiments of the present disclosure. The semiconductor devices 30C1 and 30C2 can correspond to the semiconductor device 30A in FIG. 3A or the semiconductor device 30B in FIG. 3B. The semiconductor device 30C1 can be formed on the front side of the wafer, and the semiconductor device 30C2 can be formed on the back side of the wafer.

Regarding the semiconductor device 30C1, the metal structures M01, M02, M03 and M04 extend along an X direction. The metal structures M02, M03 and M04 are provided in the same row extending along an X direction. The metal structure M04 is formed between the metal structures M02 and M03. The metal structures M01, M02, M03 and M04 are spaced apart from each other. The active region OD1 extends along an X direction. The gate structures PO1 and PO2 extend along a Y direction. In some embodiments, the metal structure M01 is electrically connected to the voltage source VDD or VSS. The metal structure M02 is electrically connected to the read word line RWL. The metal structure M03 is electrically connected to the read word line bar RWLB.

Regarding the semiconductor device 30C2, the metal structures BM01 and BM02 extend along an X direction. The metal structures BM01 and BM02 can be staggered with each other from a top-view perspective of the design layout. The metal structures BM01 and BM02 are spaced apart from each other from a top-view perspective of the design layout. The active region OD2 extends along an X direction. The metal layer structure MD1 extends along a Y direction.

In some embodiments, the metal structure BM01 overlaps the right portion of the active region OD2 from a top-view perspective of the design layout. The metal structure BM02 overlaps the left portion of the active region OD2 from a top-view perspective of the design layout. The metal structure BM02 is electrically connected to the read bit line RBL. The metal structure BM01 is electrically connected to the read bit line bar RBLB. The widths of the metal structures BM01 and BM02 can exceed those of the metal structures M01 to M04. Therefore, the resistance and the metal capacitance of the metal structures BM01 and BM02 can be decreased, and electronic migration and IR drop proportional to resistance improved, as can, accordingly, computing speed and power consumption.

FIG. 3D shows a cross-section of the semiconductor device 30D along line S3 in FIG. 3C, in accordance with some embodiments of the present disclosure. The semiconductor device 30D can correspond to the semiconductor device 30C2 of FIG. 3C. The section line S3 is parallel to and extends opposite the Y direction. The active regions OD2, OD3 and OD4 are disposed above the metal structure BM01 through three via structures VB.

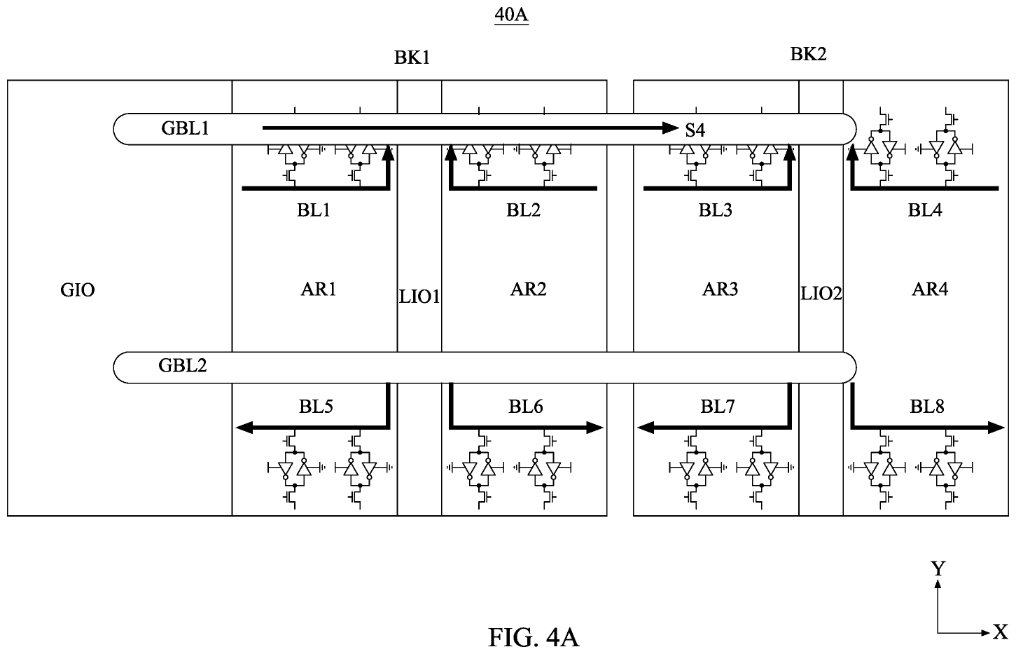

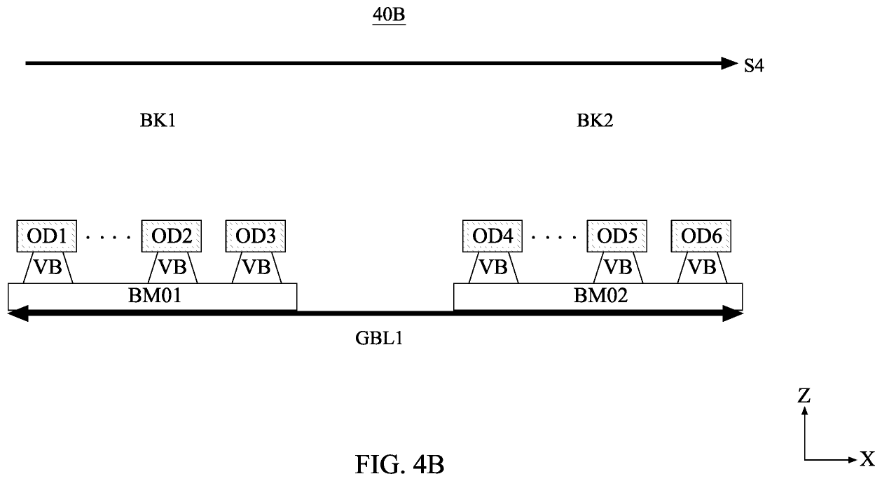

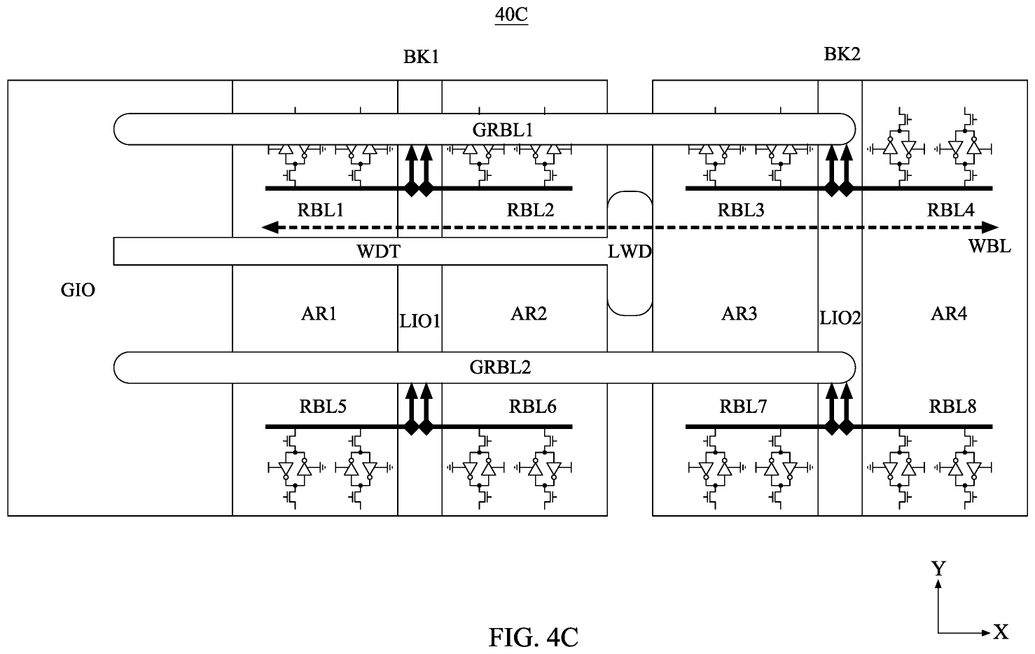

FIG. 4A is a schematic view of the semiconductor device 40A, in accordance with some embodiments of the present disclosure. The semiconductor device 40A of FIG. 4A can be similar to or correspond to the semiconductor device 10 in FIG. 1 or the semiconductor devices 30C1 and 30C2 in FIG. 3C. In some embodiments, the semiconductor device 40A can be a multi-bank memory device, for example, a multi-bank SRAM device.

Similar to the semiconductor devices 30C1 and 30C2 in FIG. 3C, the semiconductor device 40A can include a plurality of active regions, a plurality of gate structures, and a plurality of metal structures disposed on both the front side and the back side of the wafer. As shown in FIG. 4A, the semiconductor device 40A includes a global input and output element GIO, two banks BK1 and BK2, and two global bit lines GBL1 and GBL2. The global bit lines GBL1 and GBL2 can extend across the banks BK1 and BK2 for controlling and operating the banks BK1 and BK2.

In addition, the bank BK1 includes a local input and output element LIO1, and two arrays AR1 and AR2. The local input and output element LIO1 can be provided between the arrays AR1 and AR2. The bank BK2 includes a local input and output element LIO2, and two arrays AR3 and AR4. The local input and output element LIO2 can be provided between the arrays AR3 and AR4. Each of the arrays AR1 to AR4 can include multiple transistors, diodes, or inverters. The array AR1 can be electrically connected to the global bit line GBL1 through the bit line BL1 for reading or writing data. The array AR2 can be electrically connected to the global bit line GBL1 through the bit line BL2 for reading or writing data. The array AR3 can be electrically connected to the global bit line GBL1 through the bit line BL3 for reading or writing data. The array AR4 can be electrically connected to the global bit line GBL1 through the bit line BL4 for reading or writing data. The array AR1 can be electrically connected to the global bit line GBL2 through the bit line BL5 for reading or writing data. The array AR2 can be electrically connected to the global bit line GBL2 through the bit line BL6 for reading or writing data. The array AR3 can be electrically connected to the global bit line GBL2 through the bit line BL7 for reading or writing data. The array AR4 can be electrically connected to the global bit line GBL2 through the bit line BL5 for reading or writing data.

Please refer to FIGS. 1 and 4A. In some embodiments, the global bit lines GBL1 and GBL2 can be electrically connected to the metal structures on the front side 10FS of the wafer 10A, for example, the metal structures M11 and M12. The global bit lines GBL1 and GBL2 can be electrically connected to the metal structures on the back side 10BS of the wafer 10A, for example, the metal structure BM0. The bit lines BL1 to BL8 can be electrically connected to the metal structures on the front side 10FS of the wafer 10A. The local input and output elements LIO1 and LIO2 can be electrically connected to the metal structures on the front side 10FS of the wafer 10A, for example, the metal structures M01 and M02. The global input and output elements GIO can be electrically connected to the metal structures on the front side 10FS of the wafer 10A. The global input and output elements GIO can be electrically connected to the metal structures on the back side 10BS of the wafer 10A.

In some embodiments, the global bit lines GBL1 and GBL2 can be electrically connected to the metal structures on the metal structure BM0 of the back side 10BS. The widths of the metal structure BM0 can exceed those of the metal structures on the front side 10FS. Therefore, the resistance and the metal capacitance in the global bit lines GBL1 and GBL2 can be decreased and electronic migration and IR drop proportional to resistance can be improved, as can, accordingly, computing speed and power consumption.

FIG. 4B shows a cross-section of the semiconductor device 40B along the section line S4 in FIG. 4A, in accordance with some embodiments of the present disclosure. The semiconductor device 40B can correspond to the semiconductor device 40A of FIG. 4A. The section line S4 is parallel to the X direction.

The bank 1 can include the metal structure BM01 and multiple active regions OD1, OD2 and OD3. The active regions OD1, OD2 and OD3 are disposed above the metal structure BM01 through three via structures VB along a Z direction. The bank 2 can include the metal structure BM02 and several active regions OD4, OD5 and OD6. The active regions OD4, OD5 and OD6 are disposed above the metal structure BM02 through three via structures VB along a Z direction. The metal structures BM01 and BM02 are formed on the back side 10BS of the wafer 10W.

FIG. 4C is a schematic view of the semiconductor device 40C, in accordance with some embodiments of the present disclosure. The semiconductor device 40C of FIG. 4C can be similar to the semiconductor device 40A of FIG. 4A, differing therefrom only as follows. In some embodiments, the semiconductor device 40C can be a multi-bank and multi-port memory device, for example, a multi-bank and multi-port SRAM device.

As shown in FIG. 4C, the semiconductor device 40C includes a global input and output element GIO, a write data line WDT, a local write driver LWD, two banks BK1 and BK2, and two global read bit lines GRBL1 and GRBL2. The global read bit lines GRBL1 and GRBL2 can extend across the banks BK1 and BK2 for controlling and operating the banks BK1 and BK2. The local write driver LWD can be formed between the banks BK1 and BK2.

Each of the arrays AR1 to AR4 can include multiple transistors, diodes, or inverters. The array AR1 can be electrically connected to the global read bit line GRBL1 through the read bit line RBL1 for reading or writing data. The array AR2 can be electrically connected to the global read bit line GRBL1 through the read bit line RBL2 for reading or writing data. The array AR3 can be electrically connected to the global read bit line GRBL1 through the read bit line RBL3 for reading or writing data. The array AR4 can be electrically connected to the global read bit line GRBL1 through the read bit line RBL4 for reading or writing data. The array AR1 can be electrically connected to the global read bit line GRBL2 through the read bit line RBL5 for reading or writing data. The array AR2 can be electrically connected to the global read bit line GRBL2 through the read bit line RBL6 for reading or writing data. The array AR3 can be electrically connected to the global read bit line GRBL2 through the read bit line RBL7 for reading or writing data. The array AR4 can be electrically connected to the global read bit line GRBL2 through the read bit line RBL8 for reading or writing data.

Please refer to FIGS. 1 and. 4A. In some embodiments, the global read bit lines GRBL1 and GRBL2 can be electrically connected to the metal structures on the front side 10FS of the wafer 10A, for example, the metal structures M11 and M12. The global read bit lines GRBL1 and GRBL2 can be electrically connected to the metal structures on the back side 10BS of the wafer 10A, for example, the metal structure BM0. The read bit lines RBL1 to RBL8 can be electrically connected to the metal structures on the back side 10BS of the wafer 10A. The write data line WDT can be electrically connected to the metal structures on the back side 10BS of the wafer 10A. The write bit line WBL can be electrically connected to the metal structures on the back side 10BS of the wafer 10A.

The widths of the metal structures on the back side 10BS can exceed those of the metal structures on the front side 10FS. Therefore, the resistance and the metal capacitance in the global read bit lines GRBL1 and GRBL2, the read bit lines RBL1 to RBL8, the write data line WDT and the write bit line WBL can be decreased and electronic migration and IR drop proportional to resistance can be improved, as can, accordingly, computing speed and power consumption.

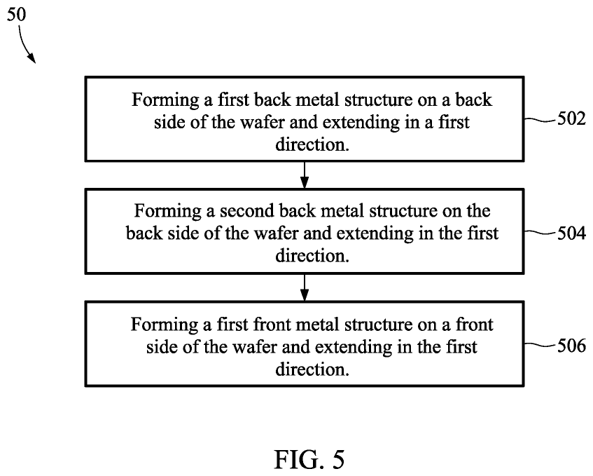

FIG. 5 is a flowchart 50 of manufacturing a semiconductor device on a wafer with super power rails, in accordance with some embodiments of the present disclosure. The flowchart 50 can correspond to the semiconductor device 10 of FIG. 1.

The flowchart 50 includes at least three operations 502, 504 and 506. In the operation 502, a first back metal structure is formed on a back side 10BS of the wafer 10A and extends along the first direction (X direction). In some embodiments, forming a metal structure includes performing one or more of lithography, deposition, etching, planarizing, or other suitable process.

In the operation 504, a second back metal structure is formed on the back side 10BS of the wafer 10A and extends along the X direction. In some embodiments, the second back metal structure is spaced apart from the first back metal structure along a second direction (Y direction) perpendicular to the X direction. In the operation 506, a first front metal structure is formed on the front side 10FS of the wafer 10A and extends in the X direction. In some embodiments, the first back metal structure and the first front metal structure are electrically connected to the power line. The second back metal structure is electrically connected to a signal line. The width of the first back metal structure along the second direction exceeds that of the first front metal structure along the second direction.

While disclosed methods (e.g., flowchart 50) are illustrated and described below as a series of acts or events, it will be appreciated that the illustrated ordering of such acts or events are not to be interpreted in a limiting sense. For example, some operations may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

Some embodiments of the present disclosure provide a semiconductor device formed on a wafer having a front side and a back side. The semiconductor device includes a first back metal structure, a second back metal structure and a first front metal structure. The first back metal structure is formed on the back side of the wafer and extending along a first direction. The second back metal structure is formed on the back side of the wafer and extending along the first direction, wherein the second back metal structure is spaced apart from the first back metal structure along a second direction perpendicular to the first direction. The first front metal structure is formed on the front side of the wafer and extending along the first direction. The first back metal structure and the first front metal structure are electrically connected to a power line for providing power to the semiconductor device, and the second back metal structure is electrically connected to a signal line for operating the semiconductor device. The width of the first back metal structure along the second direction is greater than a width of the first front metal structure along the second direction.

Some embodiments of the present disclosure provide a semiconductor device formed on a wafer having a front side and a back side. The semiconductor device includes a first global back metal structure and a plurality of banks. The first global back metal structure is formed on the back side of the wafer and extending along a first direction. Each of the banks comprises a plurality of arrays. Each of the arrays includes a plurality of first front metal structures and a plurality of active regions. The first front metal structures are formed on the front side of the wafer and extending along the first direction. The first global back metal structure extends across the banks along the first direction, and the first global back metal structure is electrically connected to the first front metal structures. The active regions extends along the first direction.

Some embodiments of the present disclosure provide a method for manufacturing a semiconductor device. The method includes forming a first back metal structure on a back side of the wafer and extending along a first direction; forming a second back metal structure on the back side of the wafer and extending along the first direction, wherein the second back metal structure is spaced apart from the first back metal structure along a second direction perpendicular to the first direction; and forming a first front metal structure on a front side of the wafer and extending along the first direction, wherein the first back metal structure and the first front metal structure are electrically connected to a power line, the second back metal structure is electrically connected to a signal line, and a width of the first back metal structure along the second direction is greater than a width of the first front metal structure along the second direction.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device formed on a wafer having a front side and a back side, comprising:
a first back metal structure formed on the back side of the wafer and extending along a first direction;
a second back metal structure formed on the back side of the wafer and extending along the first direction, wherein the second back metal structure is spaced apart from the first back metal structure along a second direction perpendicular to the first direction; and
a first front metal structure formed on the front side of the wafer and extending along the first direction, wherein the first back metal structure and the first front metal structure are electrically connected to a power line for providing power to the semiconductor device, the second back metal structure is electrically connected to a signal line for operating the semiconductor device, and a width of the first back metal structure along the second direction is greater than a width of the first front metal structure along the second direction.

2. The semiconductor device of claim 1, wherein a width of the second back metal structure along the second direction is greater than the width of the first front metal structure along the second direction.

3. The semiconductor device of claim 1, further comprising:
an active region extending along the first direction; and
a metal layer structure, extending along the second direction, wherein the active region is formed between the metal layer structure and the second back metal structure along a third direction perpendicular to the first and the second axes.

4. The semiconductor device of claim 3, wherein the semiconductor device is a memory device, and the second back metal structure is electrically connected to a match line for operating the memory device.

5. The semiconductor device of claim 4, further comprising:
a second front metal structure, extending in the second direction, wherein the second front metal structure is electrically connected to a search line or a search line bar for operating the memory device.

6. The semiconductor device of claim 5, wherein the second front metal structure is formed on the back side of the wafer.

7. The semiconductor device of claim 5, wherein the second front metal structure is formed on the front side of the wafer.

8. The semiconductor device of claim 3, wherein the semiconductor device is a multi-port memory device, and the second back metal structure is electrically connected to a read bit line for operating the memory device.

9. The semiconductor device of claim 8, further comprising a third back metal structure, extending along the first direction and formed on the back side of the wafer, wherein the third back metal structure is electrically connected to a read bit line or a read bit line bar for operating the memory device.

10. The semiconductor device of claim 9, further comprising a third front metal structure, extending along the first direction and formed on the front side of the wafer, wherein the third front metal structure is electrically connected to a read word line or a read word line bar for operating the memory device.

11. A semiconductor device formed on a wafer having a front side and a back side, comprising:
a first global back metal structure, formed on the back side of the wafer and extending along a first direction; and
a plurality of banks, wherein each of the banks comprises a plurality of arrays, and each of the arrays comprises:
a plurality of first front metal structures, formed on the front side of the wafer and extending along the first direction, wherein the first global back metal structure extends across the banks along the first direction, and the first global back metal structure is electrically connected to the first front metal structures; and
a plurality of active regions, extending along the first direction.

12. The semiconductor device of claim 11, wherein each of the banks comprises a local input and output element formed on the front side of the wafer, and the local input and output element is formed between two adjacent arrays along the first direction.

13. The semiconductor device of claim 11, wherein the first global back metal structure is electrically connected to a global bit line, and each of the first front metal structures is electrically connected to a bit line.

14. The semiconductor device of claim 11, further comprising:
a second global back metal structure, formed on the back side of the wafer and extending along the first direction, wherein the second global back metal structure extends across the banks along the first direction; and
a third global back metal structure, formed on the back side of the wafer and extending along the first direction, wherein the third global back metal structure extends across the banks along the first direction.

15. The semiconductor device of claim 14, wherein each of the arrays further comprises a plurality of second front metal structures, formed on the back side of the wafer and extending along the first direction, wherein the second global back metal structure is electrically connected to the second front metal structures.

16. The semiconductor device of claim 15, wherein the second global back metal structure is electrically connected to a global read bit line, the third global back metal structure is electrically connected to a write bit line, and each of the second front metal structures is electrically connected to a read bit line.

17. A method for manufacturing a semiconductor device on a wafer, comprising:
forming a first back metal structure on a back side of the wafer and extending along a first direction;
forming a second back metal structure on the back side of the wafer and extending along the first direction, wherein the second back metal structure is spaced apart from the first back metal structure along a second direction perpendicular to the first direction; and
forming a first front metal structure on a front side of the wafer and extending along the first direction, wherein the first back metal structure and the first front metal structure are electrically connected to a power line, the second back metal structure is electrically connected to a signal line, and a width of the first back metal structure along the second direction is greater than a width of the first front metal structure along the second direction.

18. The method of claim 17, further comprising:
forming an active region on the wafer extending along the first direction; and
forming a metal layer structure on the front side of the wafer, extending in the second direction, wherein the active region is formed between the metal layer structure and the second back metal structure along a third direction perpendicular to the first direction and the second direction.

19. The method of claim 18, wherein the semiconductor device is a memory device, and the second back metal structure is electrically connected to a match line for operating the memory device.

20. The method of claim 19, further comprising forming a second front metal structure on the front side of the wafer, extending along the second direction, wherein the second front metal structure is electrically connected to a search line or a search line bar for operating the memory device.
